(19) United States
(12) Patent Application Publication
(10) Pub. No.: US 2011/0298089 A1
(43) Pub. Date: Dec. 8, 2011

(54) TRENCH CAPACITOR AND METHOD OF FABRICATION

(75) Inventors: Rishikesh Krishnan, Hopewell Junction, NY (US); Michael P. Chudzik, Hopewell Junction, NY (US); Siddarth A. Krishnan, Hopewell Junction, NY (US)

(73) Assignee: INTERNATIONAL BUSINESS MACHINES CORPORATION, Armonk, NY (US)

(21) Appl. No.: 12/793,051

(22) Filed: Jun. 3, 2010

(51) Int. Cl. H01L 29/92; H01L 21/02

(52) U.S. Cl. 257/532; 438/386; 257/E29.342; 257/E21.008

(57) ABSTRACT

An improved trench capacitor and method of fabrication are disclosed. The trench capacitor utilizes a rare-earth oxide layer to reduce depletion effects, thereby improving performance of the trench capacitor.

### FIELD OF THE INVENTION

The present invention relates generally to a semiconductor device. More particularly, the present invention relates to a trench capacitor having improved performance characteristics.

### BACKGROUND OF THE INVENTION

Trench capacitors are widely used in Dynamic Random Access Memory (DRAM) devices for data storage. A trench DRAM cell consists of a trench capacitor and a transistor. The trench capacitor typically consists of a hole etched into the substrate, a first electrode—often referred to as a “buried plate”—in the substrate, a second electrode in the trench and, a thin storage-node dielectric which separates those two electrodes. The transistor is formed above the trench capacitor. A dielectric isolation collar may be formed in the upper region of the trench to suppress undesired parasitic leakage between the transistor and the capacitor.

A buried plate is formed in the substrate adjacent the trench by outdiffusing a dopant such as arsenic (As) into the substrate. Buried plate doping may be formed by conventional processes such as outdiffusing arsenic from a layer of arsenic-doped silicon glass (ASG) on trench sidewall, gas phase doping (GPD), plasma doping, plasma immersion ion implantation, infusion doping, or any combination of these methods that are well known in prior art. Trench capacitance enhancement may be optionally practiced before or after buried plate formation.

As the feature size of DRAM capacitors continues to reduce to 130 nanometers (nm) and lower, high permittivity dielectrics such as HfO₂ are used in order to meet the minimum requirements for capacitance and charge retention per cell while maintaining dielectric reliability at operating voltages. An unexpected problem with using high permittivity HfO₂ is a substantial increase in resistance of the silicon between the capacitor trenches. This increase in resistance is due to the silicon located between the trenches getting depleted of majority carriers even at 0V. In a metal-insulator-semiconductor capacitor, this depletion occurs when the voltage biasing is such that the n doped silicon gets depleted of majority carriers (in this case, electrons).

Metal electrodes and poly electrodes deposited on top of HfO₂ have work functions that are either pinned P-type or mid band gap due to empty unoccupied states from oxygen vacancies, dangling bonds and metal/Hi-K dielectric related interface states. As a consequence, the work function difference between the N-type silicon (Si) bottom buried plate and the top electrode is large enough to cause depletion regions in silicon that can extend even up to 150 angstroms (A). In extreme cases, the entire silicon space between the deep trenches (DTs) can get pinched off and the cross-sectional area available for current conduction can be completely shut off. Therefore, it is desirable to have an improved trench capacitor and method for fabrication that addresses the aforementioned problems, while still supporting decreased feature size.

### SUMMARY OF THE INVENTION

Embodiments of the present invention provide a trench capacitor formed in a silicon substrate. The trench capacitor comprises a rare-earth oxide layer disposed on its interior surface. A dielectric layer is then disposed on the rare-earth oxide layer, and then a conductive layer disposed on the dielectric layer.

Additional embodiments of the present invention provide a method of forming a trench capacitor. The method comprises the steps of depositing a rare-earth oxide layer on the interior surface of the trench. Then a dielectric layer is deposited on the rare-earth oxide layer, and then a conductive layer is deposited on the dielectric layer.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG).

FIG. 1 shows prior art trench capacitors.

FIG. 2 shows prior art trench capacitors with an increased depletion region.

FIG. 3 shows prior art partially fabricated trench capacitors, as the starting point for a method of fabrication in accordance with an embodiment of the present invention.

FIGS. 4-6 show trench capacitors at various fabrication steps for a method of fabrication in accordance with an embodiment of the present invention.

FIG. 7 shows trench capacitors in accordance with an embodiment of the present invention.

FIG. 8 is a flowchart indicating process steps in accordance with an embodiment of the present invention.

### DETAILED DESCRIPTION

In order to better understand embodiments of the present invention, a prior art trench capacitor is briefly discussed below.

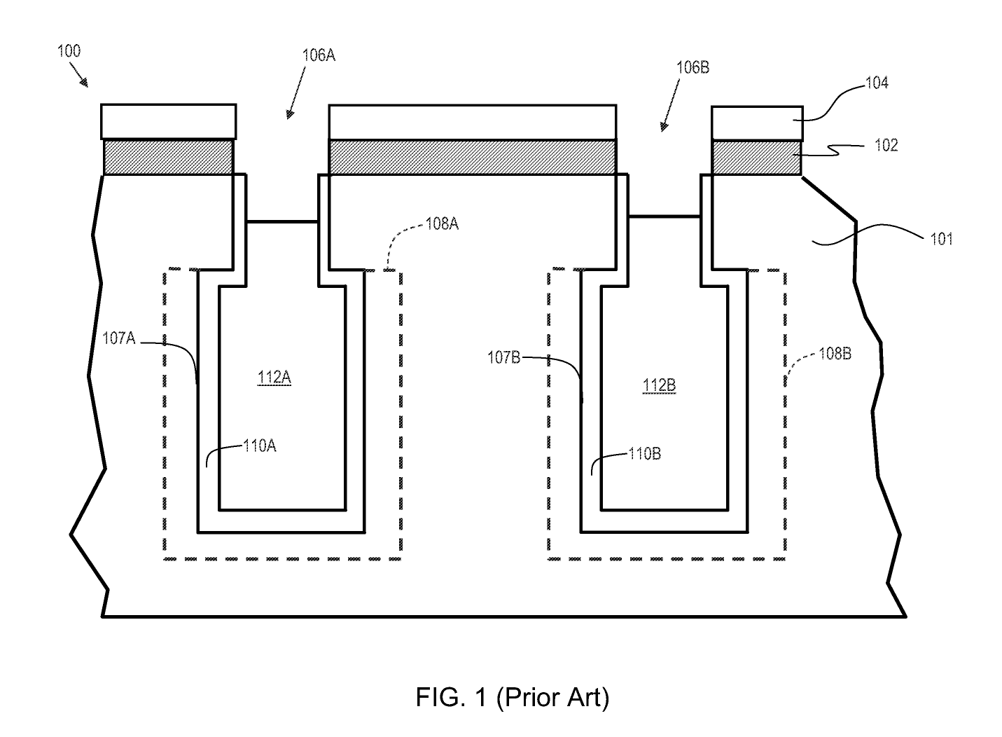

FIG. 1 illustrates a prior art semiconductor structure 100 comprising silicon substrate 101. Disposed on top of silicon substrate 101 is buried oxide layer (BOX) 102. Disposed on top of BOX 102 is silicon-on-insulator (SOI) silicon region 104. Two trench capacitors, 106A and 106B, are formed in silicon substrate 101. A dielectric layer (110A, 110B) lines each trench (107A, 107B). Note that throughout this disclosure, reference will often be made to elements ending in A, and B. Unless otherwise stated, elements with a similar suffix letter correspond to each other. For example, dielectric layer 110A lines trench 107A, and dielectric layer 110B lines trench 107B. Each trench capacitor also comprises a buried plate (108A, 108B). Each trench is filled with material (112A, 112B), which typically comprises polysilicon.

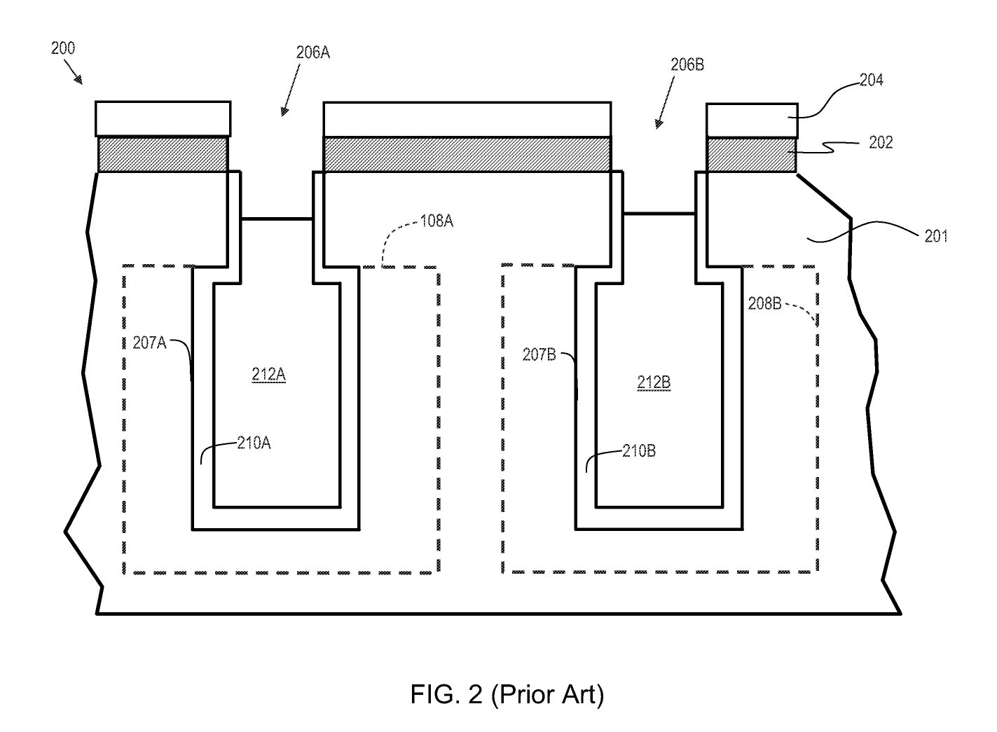

FIG. 2 illustrates a prior art semiconductor structure 200 which is similar to semiconductor structure 100 of FIG. 1, with the difference being the undesirable increase in distance between buried plate (208A, 208B) and the respective trench (207A, 207B). This is caused by an increase in depletion region size, which reduces the cross-sectional area available for current conduction, thereby degrading semiconductor performance.

Embodiments of the present invention address the depletion region issue by using a bi-layer of a high-K dielectric, such as hafnium oxide (HfO₂) and a layer of rare-earth element oxide. The rare-earth oxide (REO) is either disposed between the HfO₂ and the Si bottom plate or disposed between the top metal electrode and HfO₂ to modulate the flat band voltage and thereby control the size of the depletion. The term “flat band” refers to fact that the energy band diagram of the semiconductor is flat, which implies that no charge exists in the semiconductor. The rare-earth oxide layer induces positive fixed charges that induce corresponding negative image charges in the neighboring silicon, resulting in shifts in the flat band voltage. As a consequence, the silicon is no longer depleted at 0V and the bottom plate N-band resistance is no longer adversely impacted. Typically, the N band resistance is measured by a 4 point probe measurement. When the silicon bottom plate is depleted, the cross-section for current conduction between the deep trenches reduces, and due to the reduction in effective cross-section, the resistance increases. For example, in 32 nm and 22 nm trench geometries, the space in between trenches is small to begin with, and the depletion effect can completely block the effective cross-section for current conduction, which is undesirable. Embodiments of the present invention prevent the depletion from reaching the level where current conduction is unduly restricted.

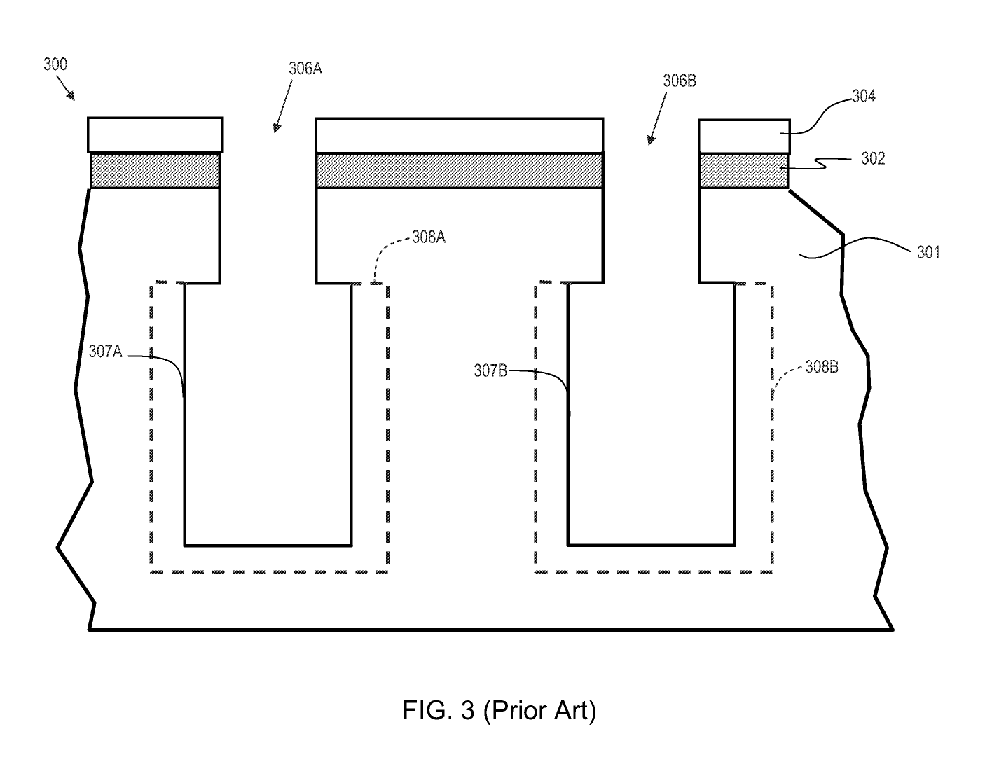

FIG. 3 shows a semiconductor structure 300, comprising prior art, partially fabricated trench capacitors, as the starting point for a method of fabrication in accordance with an embodiment of the present invention. Trenches (307A, 307B) and buried plates (308A, 308B) are formed at this stage, but no materials have been deposited in the trenches.

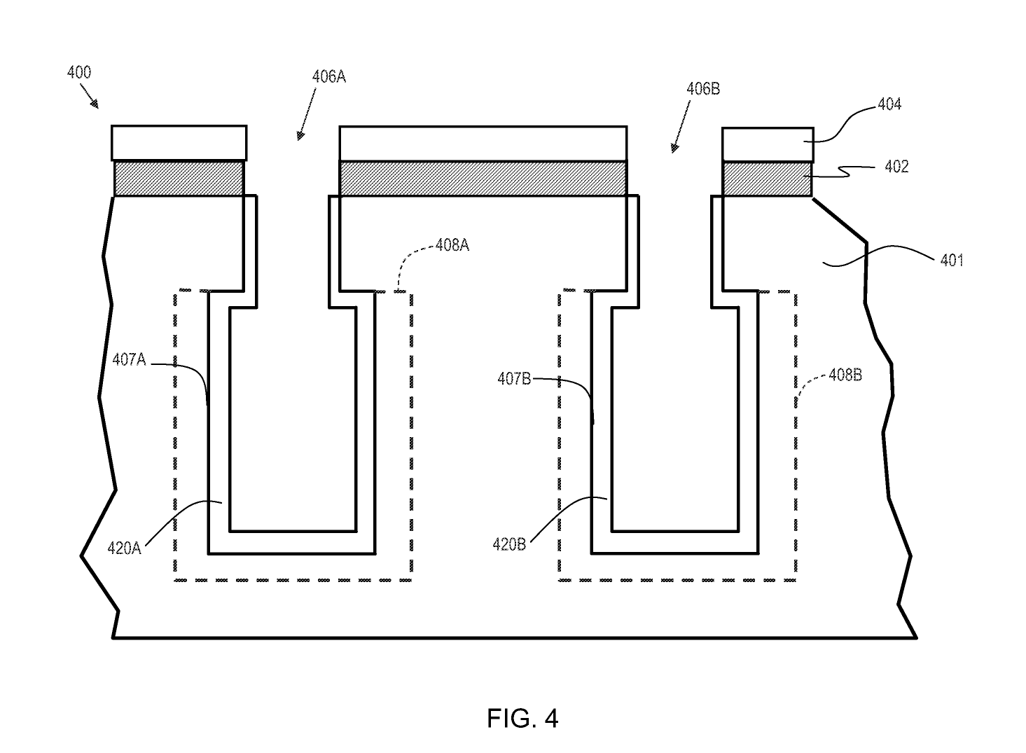

FIG. 4 shows a semiconductor structure 400, illustrating a process step in accordance with an embodiment of the present invention. Rare-earth oxide (REO) layers 420A and 420B are deposited the inner surface of trenches 407A and 407B, respectively. In one embodiment, the REO is comprised of lanthanum oxide (LaOx). Other embodiments may instead use an REO based on cerium, neodymium, erbium, or gadolinium.

In a preferred method of fabrication, the REO is deposited via atomic layer deposition (ALD). ALD is a self-limiting (the amount of film material deposited in each reaction cycle is constant), sequential surface chemistry that deposits conformal thin-films of materials onto substrates of varying compositions. While the ALD technique is known in the art, using ALD to deposit rare-earth oxides into deep trenches, while insuring uniform coverage of the trench is non-trivial. Selecting a suitable precursor is an important factor.

In one embodiment of the present invention, for a LaOx layer, a precursor of Lanthanum-thd (thd=2,2,6,6-tetramethyl-3,5-heptanedione) provides the desired thermal stability to provide uniform coverage of the LaOx layer. In an alternative embodiment, the precursor is selected from the group consisting of tris(dipivaloylmethanato)lanthanum , lanthanum(III) isopropoxide, tris(N,N-bis(trimethylsilyl)amide) lanthanum, tris(cyclopentadienyl) lanthanum, and tris(isopropyl-cyclopentadienyl) lanthanum. For other rare earth element oxides, such as cerium, neodymium and gadolinium, cyclopentadienyl, isopropoxide, and thd-based precursors may be used. In one embodiment, the thickness of the REO layer ranges from about 10 angstroms to about 20 angstroms.

In addition to an appropriate precursor, a proper pulse time is also needed to ensure optimal deposition of the REO layer. In one embodiment, the pulse time ranges from about 20 milliseconds to about 30 seconds.

In one embodiment, water is used as an oxidizer during the ALD process for depositing the REO layer. The benefit of using water is that it is a “gentle” oxidizer that oxidizes the lanthanum, but does not oxidize the silicon. If the silicon were to be oxidized, a low-K dielectric layer would be formed, which would have the undesirable effect of reducing the total effective dielectric constant.

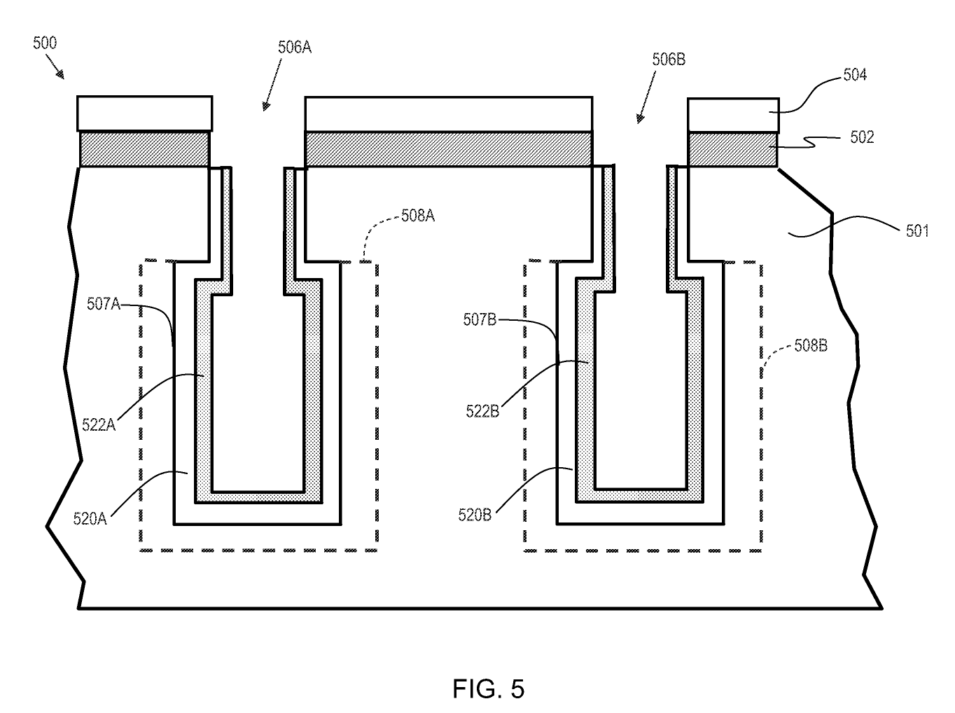

FIG. 5 shows a semiconductor structure 500, illustrating a subsequent process step in accordance with an embodiment of the present invention. A layer of High-K dielectric (522A, 522B) is deposited over the REO layer (520A, 520B). In one embodiment, the High-K dielectric layer is comprised of hafnium oxide (HfO₂). In another embodiment, Hafnium Silicate is used as the High-K dielectric (522A, 522B). In yet another embodiment, Zirconium Oxide is used as the High-K dielectric (522A, 522B). In a preferred embodiment, the High-K dielectric layer (522A, 522B) ranges in thickness from about 70 angstroms to about 100 angstroms, and is deposited via ALD.

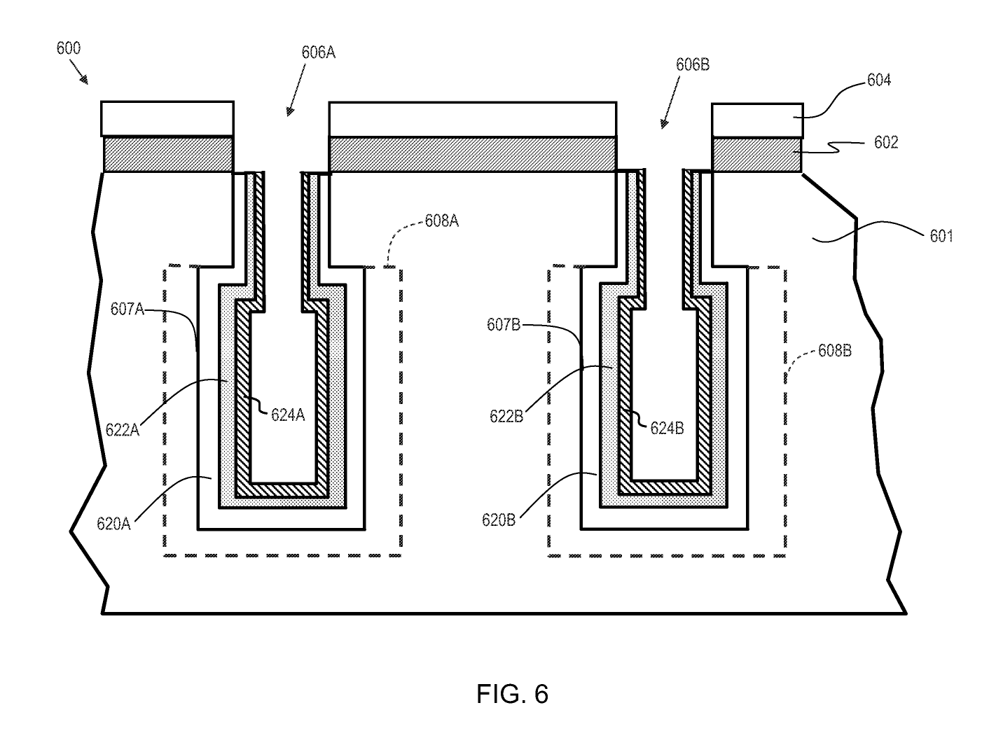

FIG. 6 shows a semiconductor structure 600, illustrating a subsequent process step in accordance with an embodiment of the present invention. A conductive layer (624A, 624B) is deposited over the High-K dielectric layer (622A, 622B). In one embodiment, conductive layer (624A, 624B) is comprised of TiN. The conductive layer (624A, 624B) may be deposited by an ALD or chemical vapor deposition (CVD) process. The TiN serves the purposes of providing conduction and decreasing the overall trench resistance. As an alternative to TiN, other materials may be used for conduction layer (624A, 624B), including, but not limited to, Ti/TiN bilayers, Ti/TaN, TaN, TiAlN, TaAlN, TiSiN, and TaSiN.

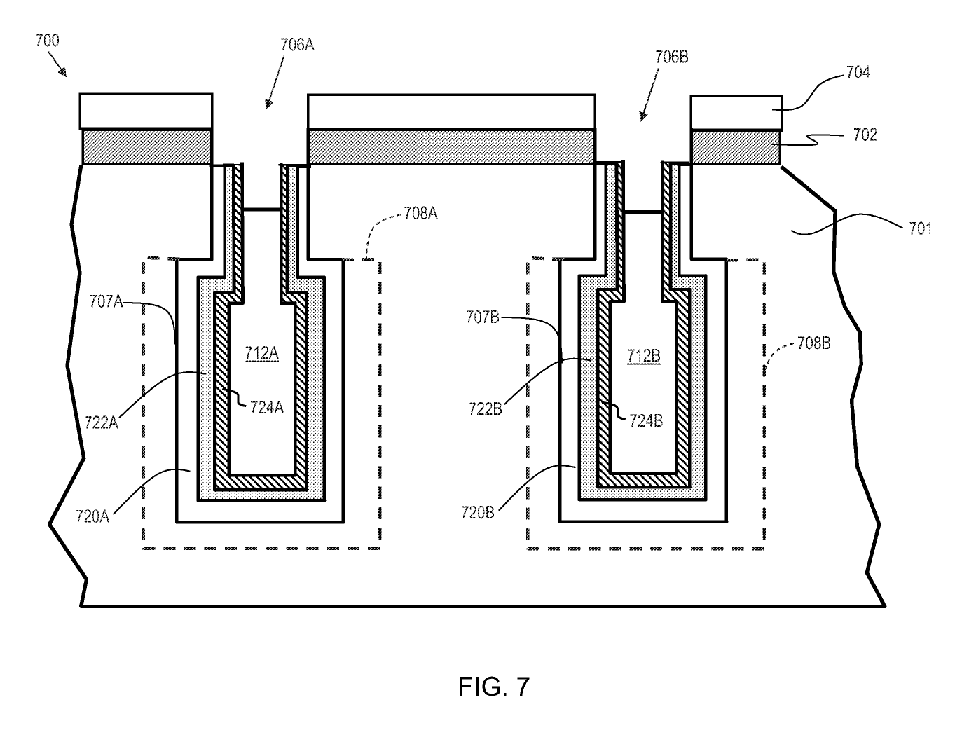

FIG. 7 shows a semiconductor structure 700, illustrating a subsequent process step in accordance with an embodiment of the present invention. Polysilicon (712A, 712B) is deposited in trenches (707A, 707B), thereby forming the trench capacitors 707A and 707B.

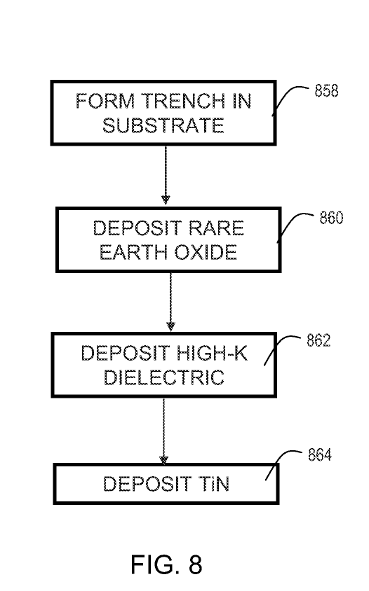

FIG. 8 is a flowchart indicating process steps in accordance with an embodiment of the present invention. In process step 858, a trench is formed in a silicon substrate. In process step 860, a rare-earth oxide, such as lanthanum oxide, is deposited on the interior surface of a trench. Process step 860 is preferably performed via atomic layer deposition (ALD). In process step 862 a high-K dielectric is deposited on to the rare-earth oxide. Process step 862 is also preferably performed using ALD. In process step 864, TiN is deposited onto the high-K dielectric layer. Process step 864 may be performed with ALD or CVD.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A trench capacitor comprising:
a trench having an interior surface formed in a silicon substrate;
a rare-earth oxide layer disposed on the interior surface of said trench;
a dielectric layer disposed on the rare-earth oxide layer; and
a conductive layer disposed on the dielectric layer.

2. The trench capacitor of claim 1, wherein the conductive layer is TiN.

3. The trench capacitor of claim 1, wherein the rare-earth oxide layer is lanthanum oxide.

4. The trench capacitor of claim 1, wherein the rare-earth oxide layer is a material from the group consisting of cerium oxide, neodymium oxide, gadolinium oxide, and erbium oxide.

5. The trench capacitor of claim 1, wherein the conductive layer is a material from the group consisting of TaN, TiAlN, TaAlN, TiSiN, and TaSiN.

6. The trench capacitor of claim 1, wherein:
the conductive layer is TiN;
the rare-earth oxide layer is a layer of lanthanum oxide;
the layer of lanthanum oxide has a thickness ranging from about 10 angstroms to about 20 angstroms;
the dielectric layer is hafnium oxide; and
wherein the dielectric layer ranges from about 70 angstroms to about 100 angstroms.

7. The trench capacitor of claim 1, wherein the dielectric layer is hafnium oxide.

8. The trench capacitor of claim 1, wherein the dielectric layer is hafnium silicate.

9. The trench capacitor of claim 1, wherein the dielectric layer is zirconium oxide.

10. The trench capacitor of claim 3, wherein the rare-earth oxide layer has a thickness ranging from about 10 angstroms to about 20 angstroms.

11. The trench capacitor of claim 10, wherein the thickness of the dielectric layer ranges from about 70 angstroms to about 100 angstroms.

12. A method of forming a trench capacitor, comprising:
forming a trench in a silicon substrate;
depositing a rare-earth oxide layer on the interior surface of the trench;
depositing a dielectric layer on the rare-earth oxide layer; and
depositing a conductive layer on the dielectric layer.

13. The method of claim 12, wherein depositing a rare-earth oxide layer is performed via atomic layer deposition.

14. The method of claim 13, wherein the atomic layer deposition is performed using a precursor comprised of lanthanum-thd.

15. The method of claim 13, wherein the atomic layer deposition is performed using a precursor selected from the group consisting of tris(dipivaloylmethanato)lanthanum, lanthanum(III) isopropoxide, tris(N,N-bis(trimethylsilyl)amide) lanthanum, tris(cyclopentadienyl) lanthanum, and tris(isopropyl-cyclopentadienyl) lanthanum.

16. The method of claim 14, wherein the atomic layer deposition is performed using an oxidizer comprised of water.

17. The method of claim 16, wherein the atomic layer deposition is performed using a pulse time ranging about 20 milliseconds to about 30 seconds.

18. The method of claim 12, wherein depositing a dielectric layer is performed via atomic layer deposition.

19. The method of claim 12, wherein depositing a conductive layer comprises depositing TiN via atomic layer deposition.

20. The method of claim 12, wherein depositing a conductive layer comprises depositing TiN via chemical vapor deposition.
